(19) United States
(12) Patent Application Publication
(10) Pub. No.: US 2013/0001566 A1
(43) Pub. Date: Jan. 3, 2013

(54) BACK PLANE FOR USE IN FLAT PANEL DISPLAYS AND METHOD OF MANUFACTURING THE BACK PLANE

(75) Inventors: Jong-Han Jeong, Yongin-City (KR); Chaun-Gi Choi, Yongin-City (KR)

(73) Assignee: SAMSUNG MOBILE DISPLAY CO., LTD, Yongin-City (KR)

(21) Appl. No.: 13/460,354

(22) Filed: Apr. 30, 2012

(30) Foreign Application Priority Data
Jun. 28, 2011 (KR) 10-2011-0063033

(51) Int. Cl. H01L 51/52; H01L 51/56

(52) U.S. Cl. 257/59; 257/72; 438/34; 257/40; 257/E51.018

(57) ABSTRACT

In one aspect, a back plane for use in flat panel displays is provided. The back plane may include a substrate; an auxiliary layer; a source electrode and a drain electrode; an active layer; a first insulation layer; a gate electrode; and a second insulation layer.

### CROSS-REFERENCE TO RELATED APPLICATION

This application claims priority to and the benefit of Korean Patent Application No. 10-2011-0063033 filed in the Korean Intellectual Property Office on Jun. 28, 2011, the disclosure of which is incorporated herein by reference in its entirety.

### BACKGROUND

1. Field

The present embodiments relates to a back plane for use in flat panel displays and a method of manufacturing the back plane, and more particularly, to a back plane for use in flat panel displays that includes an oxide semiconductor thin film transistor (TFT), and a method of manufacturing the back plane.

2. Description of the Related Technology

Flat panel displays such as organic light-emitting display devices and liquid crystal displays (LCDs) are manufactured on a substrate on which a pattern including at least one thin film transistor (TFT), a capacitor, and wiring connecting the TFT to the capacitor is formed to drive the flat panel displays. The TFT includes an active layer that provides a channel area, a source area, and a drain area, and a gate electrode that is formed above the channel region and is electrically insulated from the active layer by a gate insulation layer.

The active layer of the TFT is generally formed of a semiconductor material such as amorphous silicon or poly-silicon. When the active layer is formed of amorphous silicon, the mobility of the active layer is low, and thus it is difficult to realize a driving circuit operating at high speed. When the active layer is formed of poly-silicon, the mobility of the active layer is high, but a threshold voltage is non-uniform. Thus, a special compensation circuit is needed. A conventional TFT manufacturing method using low- temperature poly-silicon (LTPS) includes an expensive process such as laser thermal treatment. Thus, equipment investment costs and maintenance costs are high, and a conventional TFT is not suitable for large-area substrates. To address these problems, research into the use of an oxide semiconductor to form an active layer has been recently conducted.

### SUMMARY

The present embodiments provides a back plane for use in flat panel displays that includes an oxide semiconductor thin film transistor (TFT) of a top-gate type and a bottom-contact type, and a method of manufacturing the back plane.

According to an aspect of the present embodiments, there is provided a back plane for use in flat panel displays, the back plane comprising: a substrate; an auxiliary layer formed on the substrate and comprising a first trench and a second trench; a source electrode and a drain electrode formed on the substrate and embedded in the first trench, and a lower capacitor electrode embedded in the second trench and formed on the substrate on which the source electrode and the drain electrode are formed; an active layer formed on the auxiliary layer to contact the source electrode and the drain electrode; a first insulation layer formed on the auxiliary layer to cover the active layer; a gate electrode formed on the first insulation layer to face the active layer, and an upper capacitor electrode formed on the first insulation layer on which the gate electrode is formed, to face the lower capacitor electrode; and a second insulation layer formed on the first insulation layer to cover the gate electrode and the upper capacitor electrode.

According to another aspect of the present embodiments, there is provided a method of manufacturing a back plane for use in flat panel displays, the method comprising: a first mask process of forming an auxiliary layer on a substrate and forming a first trench and a second trench in the auxiliary layer; a second mask process of forming a source electrode and a drain electrode on the substrate to be embedded in the first trench, and forming a lower capacitor electrode on the substrate on which the source electrode and the drain electrode are formed, to be embedded in the second trench; a third mask process of forming an active layer on the auxiliary layer to contact the source electrode and the drain electrode; forming a first insulation layer on the auxiliary layer to cover the active layer; a fourth mask process of forming a gate electrode on the first insulation layer to face the active layer, and forming an upper capacitor electrode on the first insulation layer on which the gate electrode is formed, to face the lower capacitor electrode; and forming a second insulation layer on the first insulation layer to cover the gate electrode and the upper capacitor electrode.

### BRIEF DESCRIPTION OF THE DRAWINGS

The above and other features and advantages of the present embodiments will become more apparent by describing in detail exemplary embodiments thereof with reference to the attached drawings where like references numbers indicate identical or functionally similar elements.

FIG. 1 is a schematic cross-sectional view of a back plane for use in flat panel displays according to an example of the present embodiments;

FIGS. 2 through 12 are schematic cross-sectional views for describing a method of manufacturing the back plane of FIG. 1;

FIG. 13 is a schematic cross-sectional view of a back plane for use in flat panel displays according to another example of the present embodiments; and

FIGS. 14 through 22 are schematic cross-sectional views for describing a method of manufacturing the back plane of FIG. 13.

### DETAILED DESCRIPTION

It is to be appreciated that all changes, equivalents, and substitutes that do not depart from the spirit and technical scope of the present embodiments are encompassed in the present embodiments.

While such terms as “first,” “second,” etc., may be used to describe various components, such components must not be limited to the above terms. The above terms are used only to distinguish one component from another.

The terms used in the present specification are merely used to describe particular embodiments, and are not intended to be limiting. An expression used in the singular encompasses the expression in the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

The present embodiments will now be described more fully with reference to the accompanying drawings in which exemplary embodiments of the embodiments are shown.

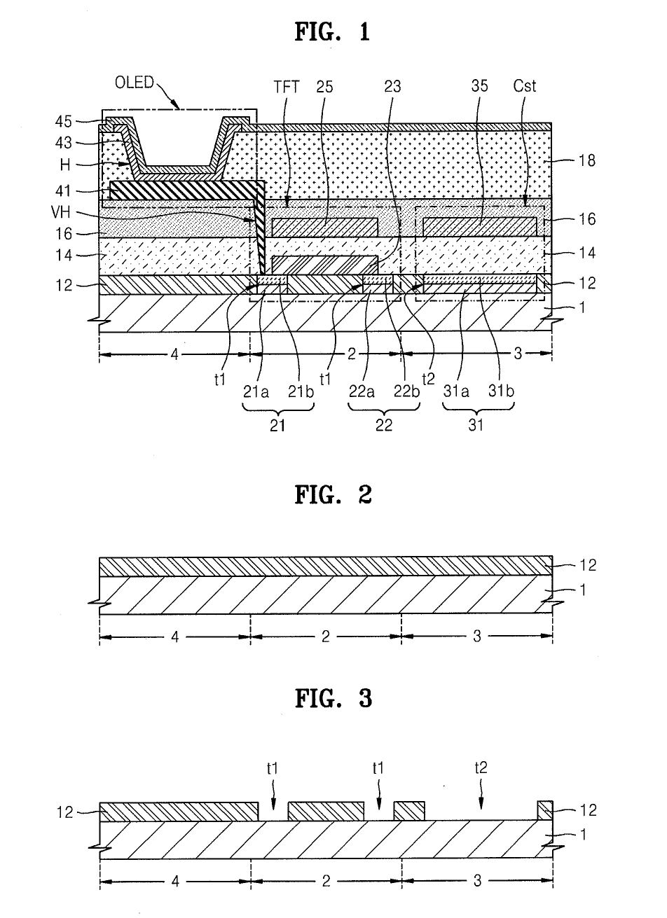

FIG. 1 is a schematic cross-sectional view of a back plane for use in flat panel displays of the present embodiments.

Referring to FIG. 1, the back plane for use in flat panel displays includes a transistor region 2, a storage region 3, and a light-emitting region 4.

The transistor region 2 includes a thin film transistor (TFT) serving as a driving device. The TFT includes an active layer 23, a gate electrode 25, and source and drain electrodes 22 and 21. In terms of structure, the TFT according to the present embodiment may be a top-gate type in which the gate electrode 25 exists above the active layer 23 and a bottom-contact type in which the source electrode 22 and the drain electrode 21 contact a bottom surface of the active layer 23. In terms of material, the TFT according to the present embodiment may be an oxide semiconductor TFT including an oxide semiconductor in the active layer 23.

The source electrode 22 and the drain electrode 21 of the TFT are embedded in a first trench t1 formed in an auxiliary layer 12 on the substrate 1. The source electrode 22 and the drain electrode 21 include at least first layers 21a and 22a, respectively, and second layers 21b and 22b, respectively, sequentially stacked on the substrate 1. The second layers 21b and 22b include low-resistance materials less reactive to oxide semiconductor than the first layers 21a and 22a. For example, the first layers 21a and 22a may include aluminum (Al) that is highly reactive to oxide semiconductor. The second layer 21b and 22b may include at least one selected from among silver (Ag), magnesium (Mg), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), MoW, and copper (Cu) that is less reactive to oxide semiconductor. The active layer 23 is formed on the source electrode 22 and the drain electrode 21 so as to contact the source and drain electrodes 22 and 21. In detail, a source area (not shown) and a drain area (not shown) are formed on both edges, respectively, of the active layer 23, and are connected to the source and drain electrodes 22 and 21, respectively. A first insulation layer 14 as a gate insulation layer for insulating the gate electrode 25 from the active layer 23 is formed on the auxiliary layer 12 so as to cover the active layer 23. The gate electrode 25 is formed on the first insulation layer 14 so as to face the active layer 23.

An aspect of the present embodiments provides a structure allowing a low-resistance material, which is included in the source electrode 22 and the drain electrode 21 and is highly reactive to the oxide semiconductor, to not directly contact the oxide semiconductor. Accordingly, a back plane, for use in flat panel displays, that has a TFT with a high electrical contact property and a capacitor Cst with an increased capacity obtained due to reduction of the thickness of an insulation layer between the active layer 23 and the gate electrode 25 may be obtained.

In some embodiments, the storage region 3 includes the capacitor Cst. In some embodiments, the capacitor Cst includes a lower electrode 31 and an upper electrode 35, and the first insulation layer 14 is interposed between the lower electrode 31 and the upper electrode 35. In some embodiments, the lower electrode 31 may be formed on the same layer on the layer on which the source electrode 22 and the drain electrode 21 of the TFT are formed. In some embodiments, the lower electrode 31 is embedded in a second trench t2 formed in the auxiliary layer 12 on the substrate 1. In some embodiments, the lower electrode 31 may include a first layer 31a and a second layer 32b similar to the source electrode 22 and the drain electrode 21, and the first and second layers 31a and 31b may be formed of the same materials as those used to form the first layers 21a and 22a and the second layers 21b and 22b of the source and drain electrodes 22 and 21. In some embodiments, the upper electrode 35 may be formed of the same material as that used to form the gate electrode 25 of the TFT, on the same layer as the layer on which the gate electrode 25 is formed.

Since the lower electrode 31 of the capacitor Cst according to the present embodiment can be embedded in the second trench t2 formed in the auxiliary layer 12, the thickness of the first insulation layer 14 interposed between the lower electrode 31 and the upper electrode 35 may be reduced. Accordingly, the capacity of the capacitor Cst may be increased and reduction of an aperture ratio of the capacitor Cst may be prevented, without needing to increase the areas of the upper electrode 35 and the lower electrode 31 of the capacitor Cst.

In some embodiments, the light-emitting region 4 includes an organic light-emitting diode (OLED). In some embodiments, the OLED includes a pixel electrode 41 connected to the source or drain electrode 22 or 21 of the TFT, an opposite electrode 45 formed to face the pixel electrode 41, and an intermediate layer 43 interposed between the pixel electrode 41 and the opposite electrode 45 and including an organic emission layer.

According to an embodiment of the present embodiments, since the OLED is included in the light-emitting region 4, the back plane of FIG. 1 may be used as a back plane for use in organic light emitting displays. However, aspects of the present embodiments are not limited to this configuration. For example, if liquid crystal is included between the pixel electrode 41 and the opposite electrode 45, the back plane of FIG. 1 may be used as a back plane for use in liquid crystal displays (LCDs).

FIGS. 2 through 12 are schematic cross-sectional views for describing a method of manufacturing the back plane of FIG. 1. The method of manufacturing the back plane of FIG. 1 will now be described.

First, as shown in FIG. 2, the auxiliary layer 12 is formed on an upper surface of the substrate 1. The substrate 1 may be formed of a transparent glass material containing SiO₂ as a main component. However, the substrate 1 is not limited thereto. In some embodiments, the substrate 1 may be any substrate formed of various materials, for example, a transparent plastic, a metal, or the like.

In some embodiments, the auxiliary layer 12, for example, a barrier layer, a blocking layer, and/or a buffer layer, may be formed on the upper surface of the substrate 1 to prevent diffusion of impurity ions and penetration of moisture or external air and to planarize the upper surface of the substrate 1. In some embodiments, the auxiliary layer 12 may be formed using, for example, SiO₂ and/or SiNₓ, according to any of various deposition methods, for example, plasma enhanced chemical vapor deposition (PECVD), atmospheric pressure CVD (APCVD), and low pressure CVD (LPCVD).

First, as shown in FIG. 3, the first trench t1 and the second trench t2 are formed in the auxiliary layer 12.

In some embodiments, the first trench t1 and the second trench t2 are obtained by patterning the auxiliary layer 12 according to a mask process using a first mask (not shown).

In some embodiments, the first trench t1 is formed in the transistor region 2, and the second trench t2 is formed in the storage region 3. In some embodiments, the first and second trenches t1 and t2 may have depths equal to or smaller than the thickness of the auxiliary layer 12.

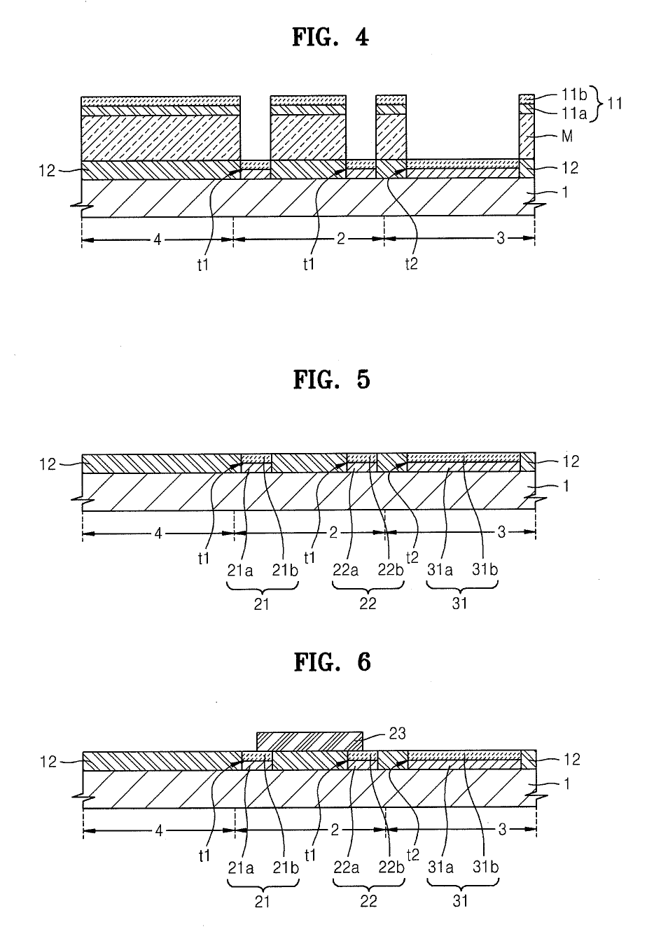

Next, as shown in FIGS. 4 and 5, the source electrode 22 and the drain electrode 21 of the TFT are formed to be embedded in the first trench t1, and the lower electrode 31 of the capacitor Cst is formed to be embedded in the second trench t2.

In some embodiments, the source and drain electrodes 22 and 21 and the lower electrode 31 of the capacitor Cst are obtained by patterning according to a mask process using a second mask (not shown) and a lift-off method.

The lift-off method denotes a method in which a thin film is formed on the entire surface of a substrate with a masking layer remaining in an area where the thin film should not be formed, and the masking layer is removed, so that only a portion of the thin film formed on the substrate remains and a portion of the thin film existing on the masking layer is lifted off. In other words, the lift-off method involves a principle whereby a masking layer is first formed in a pattern opposite to a desired pattern, a thin film is formed on a resultant structure, and then the masking layer is removed, resulting in a portion of the thin film covered by the masking layer disappearing to obtain the desired pattern.

First, referring to FIG. 4, a masking layer M is formed on a portion of the auxiliary layer 12 other than a portion where the first trench t1 and the second trench t2 have been formed, by using a second mask (not shown). Then, a first metal layer 11 is formed on the entire surface of the substrate 1. In some embodiments, the first metal layer 11 is embedded in the first trench t1 and the second trench t2 and covers the masking layer M. In some embodiments, the first metal layer 11 may include at least a first layer 11a and a second layer 11b sequentially stacked on the substrate 1. For example, the first layer 11a may include Al, and the second layer 11b may include at least one component selected from the group consisting of silver (Ag), magnesium (Mg), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), MoW, and copper (Cu). In some embodiments, the first metal layer 11 may have a three-layered structure, namely, an Mo—Al—Mo structure. In some embodiments, the first metal layer 11 may be formed by sputtering, evaporation-deposition, e-beam deposition, thermal deposition, or the like. In some embodiments, the thickness of the first metal layer 11 may be smaller than or equal to the depth of the first or second trenches t1 or t2. In some embodiments, the masking layer M is formed to have a thickness about two to three times greater than that of the first metal layer 11, in order to be easily removed in a subsequent process. When the first metal layer 11 is formed using a sputtering method using plasma, a masking material such as a positive photoresist that is highly resistant to the plasma can be used.

Next, referring to FIG. 5, the masking layer M and a portion of the first metal layer 11 existing on the upper surface of the masking layer M are both removed to obtain the source and drain electrodes 22 and 21 embedded in the first trench t1 and the lower electrode 31 embedded in the second trench t2. In some embodiments, the source and drain electrodes 22 and 21 and the lower electrode 31 include at least the first layers 21a, 22a, and 31a, respectively, and the second layers 21b, 22b, and 31b, respectively. In some embodiments, the source and drain electrodes 22 and 21 and the lower electrode 31 may each have a three-layered structure, namely, an Mo—Al—Mo structure. The upper surfaces of the source and drain electrodes 22 and 21 and the lower electrode 31 are on the same level as or lower than the upper surface of the auxiliary layer 12.

According to an aspect of the present embodiments, the upper surfaces of the source and drain electrodes 22 and 21 are on the same level as or lower than the upper surface of the auxiliary layer 12, so that the first layers 21a and 22a do not protrude out of the auxiliary layer 12. Thus, oxidation of the first layers 21a and 22a due to direct contact with the active layer 23 may be prevented. In addition, since the upper surface of the lower electrode 31 is on the same level as or lower than the upper surface of the auxiliary layer 12, the thickness of the first insulation layer 14 of FIG. 1 as a dielectric layer between the lower electrode 31 and the upper electrode 35 may be reduced, thereby increasing the capacity of the capacitor Cst.

In some embodiments, the source and drain electrodes 22 and 21 are not embedded in the first trench t1, the active layer 23 contacts the upper surface and lateral surface of the source and drain electrodes 22 and 21 and thus may directly contact the first layers 21a and 22a. In some embodiments, the first layers 21a and 22a include a low- resistance material that is highly reactive to the oxide semiconductor. For example, when the first layers 21a and 22a include Al, the Al reacts with oxygen atoms (O) of the oxide emiconductor to generate an aluminum oxide (AlOx) which is an insulation material. Accordingly, contact between the source and drain electrodes 22 and 21 and the active layer 23 degrades. Consequently, since the source and drain electrodes 22 and 21 are embedded in the first trench t1, contact characteristics of the TFT are not degraded.

Although the source electrode 22 and the lower electrode 31 are separated from each other in the present embodiment, the source electrode 22 and the lower electrode 31 may be integrally formed.

Next, referring to FIG. 6, the active layer 23 is formed on the auxiliary layer 12 so as to contact the source and drain electrodes 22 and 21.

In some embodiments, the active layer 23 is patterned according to a mask process using a third mask (not shown).

In some embodiments, the source area (not shown) and a drain area (not shown) on both edges, respectively, of the active layer 23, are overlapped with at least parts of the upper surfaces of the source and drain electrodes 22 and 21, respectively, and are thus electrically connected to the source and drain electrodes 22 and 21. In some embodiments, the active layer 23 may include the oxide semiconductor. In some embodiments, the oxide semiconductor may include at least one selected from the group consisting of indium (In), gallium (Ga), stannum (Sn), zirconium (Zr), vanadium (V), hafnium (Hf), cadmium (Cd), germanium (Ge), and zinc (Zn). For example, the oxide semiconductor may be formed of Ga, In, and Zn in an atomic percent (atom %) ratio of 2:2:1. However, the formation of the oxide semiconductor is not limited thereto, and the oxide semiconductor may be formed of at least one component selected from the group consisting of InGaZnO, SnO₂, In₂O₃, ZnO, CdO, Cd₂SnO₄, TiO₂, and Ti₃N₄.

According to an aspect of the present embodiments, the oxide semiconductor TFT has higher mobility than a conventional silicon (Si) TFT, so that special ion doping for increasing the mobility is not required. Moreover, the oxide semiconductor TFT has polycrystalline and amorphous structures even at room temperature and thus does not require a special annealing process. Thus, in some embodiments, the oxide semiconductor TFT may even be manufactured using a low-temperature process. Since an active layer may also be formed by, for example, sputtering, the oxide semiconductor TFT may also be applied to large-area substrates.

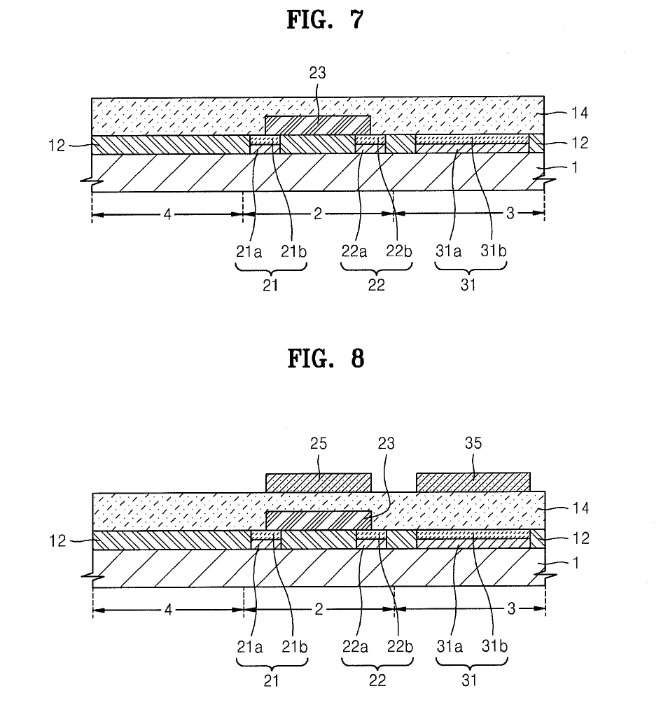

Next, referring to FIG. 7, the first insulation layer 14 is formed on the auxiliary layer 12 so as to cover the active layer 23.

In some embodiments, the first insulation layer 14 may be obtained by depositing an inorganic insulation material such as SiNₓ or SiOₓ according to a method such as plasma-enhanced chemical vapor deposition (PECVD), atmospheric pressure chemical vapor deposition (APCVD), or low pressure chemical vapor deposition (LPCVD). However, the present embodiments are not limited thereto, and an organic insulation layer or a stack of an organic insulation layer and an inorganic insulation layer may be used as the first insulation layer 14. In some embodiments, the first insulation layer 14 is disposed between the active layer 23 and the gate electrode 25 of the TFT to serve as a gate insulation layer of the TFT, and is also disposed between the upper electrode 35 and the lower electrode 31 to serve as a dielectric layer of the capacitor Cst.

According to an aspect of the present embodiments, the first insulation layer 14 may be thinly formed to increase the capacity of the capacitor Cst without increasing the areas of the upper electrode 35 and the lower electrode 31. If the source and drain electrodes 22 and 21 and the lower electrode 31 are not embedded in trenches, the first insulation layer 14 may need to be formed to a sufficient thickness to cover the source and drain electrode 22 and 21 and the lower electrode 31. In other words, the thickness of the dielectric layer of the capacitor Cst can be increased. However, according to an aspect of the present embodiments, the first insulation layer 14 may be formed sufficiently thinly by using a trench structure.

Next, referring to FIG. 8, the gate electrode 25 and the upper electrode 35 of the capacitor Cst are formed on the first insulation layer 14.

In some embodiments, the gate electrode 25 and the upper electrode 35 of the capacitor Cst are formed by patterning according to a mask process using a fourth mask (not shown).

In some embodiments, the gate electrode 25 is formed to face the active layer 23 of the transistor region 2, and the upper electrode 35 is formed to face the lower electrode 31. In some embodiments, the gate electrode 25 may be formed of the material used to form the upper electrode 35, on the same layer as the layer on which the upper electrode 35 is formed. For example, the gate electrode 25 and the upper electrode 35 may include at least one component selected from the group consisting of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), MoW, and copper (Cu).

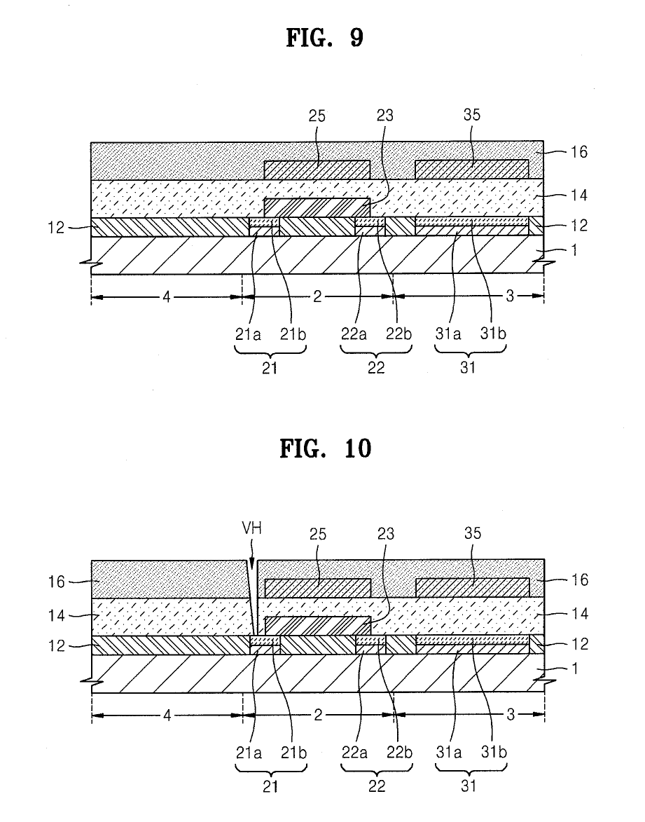

Next, referring to FIG. 9, a second insulation layer 16 is formed on the first insulation layer 14 so as to cover the gate electrode 25 and the upper electrode 35.

In some embodiments, the second insulation layer 16 is formed of at least one organic insulation material selected from the group consisting of polyimide, polyamide (PA), acryl resin, benzocyclobutene (BCB) and phenolic resin by using a method such as spin coating. In some embodiments, the second insulation layer 16 may be formed of a material selected from the group consisting of SiO₂, SiNₓ, Al₂O₃, CuOₓ, Tb₄O₇, Y₂O₃, Nb₂O₅, and Pr₂O₃ instead of the above-described organic insulation material. In some embodiments, the second insulation layer 16 may have a multi-layered structure by alternating an organic insulation material with an inorganic insulation material. In some embodiments, the second insulation layer 16 may be formed to have a sufficient thickness, for example, to be thicker than the first insulation layer 14, and may play a role of a planarization layer for planarizing the surface on which the pixel electrode 41 of FIG. 1 is to be formed or play a role of a passivation layer for protecting the gate electrode 25 and the upper electrode 35.

Next, referring to FIG. 10, the first insulation layer 14 and the second insulation layer 16 are patterned to form a via hole (VH) exposing the source electrode 22 or the drain electrode 21.

In some embodiments, the via hole (VH) may be formed by patterning according to a mask process using a fifth mask (not shown).

In some embodiments, the via hole (VH) electrically connects the pixel electrode 41 of FIG. 1 to the TFT. Although the via hole (VH) can be formed to expose the drain electrode 21 as shown in FIG. 10, the present embodiments are not limited thereto. In some embodiments, the position and shape of the via hole (VH) may vary without being limited to those illustrated in the drawings.

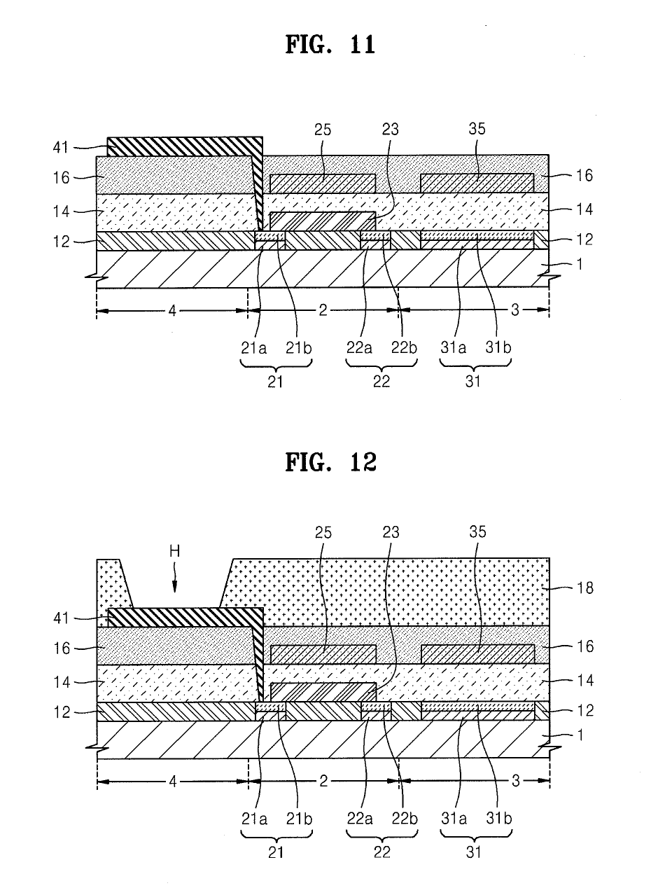

Next, referring to FIG. 11, the pixel electrode 41 electrically connected to the source electrode 22 or the drain electrode 21 is formed on the second insulation layer 16.

In some embodiments, the pixel electrode 41 may be formed by patterning according to a mask process using a sixth mask (not shown).

In some embodiments, the pixel electrode 41 is connected to the light-emission region 4 and contacts the source electrode 22 or the drain electrode 21 via the via hole (VH). Although the pixel electrode 41 can contact the drain electrode 21 as shown in FIG. 10, the present embodiments are not limited thereto. In some embodiments, the pixel electrode 41 may be formed of any of various materials according to the light emission types of organic light emitting displays. For example, in a bottom-emission type where an image is displayed toward the substrate 1 or a dual-emission type where an image is displayed both toward the substrate 1 and counter to the substrate 1, the pixel electrode 41 is formed of a transparent metal oxide. In some embodiments, the pixel electrode 41 may include at least one selected from the group consisting of ITO (indium tin oxide), IZO (indium zinc oxide), ZnO (zinc oxide), and In₂O₃. In these types, as illustrated in the drawings, the light-emission region 4 is designed not to overlap with the transistor region 2 and the storage region 3. In a top-emission type where an image is displayed counter to the substrate 1, the pixel electrode 41 may further include a reflective electrode formed of a material that reflects light. In this type, although not illustrated in the drawings, the light-emission region 4 is designed to overlap with the transistor region 2 and the storage region 3.

Next, as illustrated in FIG. 12, a third insulation layer 18 is formed on the pixel electrode 41 and is patterned to form a hole H exposing the pixel electrode 41.

In some embodiments, the hole H may be formed by patterning according to a mask process using a seventh mask (not shown).

In some embodiments, the third insulation layer 18 is formed of at least one organic insulation material selected from the group consisting of polyimide, polyamide (PA), acryl resin, benzocyclobutene (BCB) and phenolic resin by using a method such as spin coating. In some embodiments, the third insulation layer 18 may have a multi-layered structure by alternating an organic insulation material with an inorganic insulation material. In some embodiments, the third insulation layer 18 forms a hole H exposing a center portion of the pixel electrode 41, thereby defining a pixel.

In some embodiments, an intermediate layer 43 including an emission layer, and an opposite electrode 45 are formed in the hole H exposing the pixel electrode 41.

In some embodiments, the intermediate layer 43 may be formed by stacking an organic emission layer (EML) and at least one function layer selected from the group consisting of a hole injection layer (HIL), a hole transport layer (HTL), an electron transport layer (ETL), and an electron injection layer (EIL).

In some embodiments, the intermediate layer 43 may be formed of a low-molecular weight organic material or a large-molecular weight organic material.

In some embodiments, when the intermediate layer 43 is formed of a low-molecular weight organic material, the intermediate layer 43 is obtained by stacking the HTL, the HIL, and the like on a surface of the organic emission layer facing the pixel electrode 41 and stacking the ETL, the EIL, and the like on a surface of the organic emission layer facing the opposite electrode 45. Various other layers may be stacked if necessary. Examples of organic materials that may be used to form the organic emission layer include any of various materials such as copper phthalocyanine (CuPc), N,N′-di(naphthalene-1-yl)-N,N′-diphenyl-benzidine (NPB), and tris-8-hydroxyquinoline aluminum (Alq3).

In some embodiments, when the intermediate layer 43 is formed of a high- molecular weight organic material, the intermediate layer 43 may be formed by stacking only a HTL on the surface of the organic emission layer facing the pixel electrode 41. In some embodiments, the HTL may be formed of poly-(2,4)-ethylene-dihydroxy thiophene (PEDOT), polyaniline (PANI), or the like on the upper surface of the pixel electrode 41 by inkjet printing or spin coating. High-molecular weight organic materials such as polyphenylenevinylenes (PPVs) and polyfluorenes may be used as the organic materials that may be used to form the organic emission layer. A color pattern may be formed by using a typical method such as inkjet printing, spin coating, or a thermal transfer method using a laser.

In some embodiments, the opposite electrode 45 may be formed on the entire surface of the substrate 1 so as to serve as a common electrode. In some embodiments, the pixel electrode 41 can be used as an anode electrode, and the opposite electrode 45 is used as a cathode electrode. In some embodiments, the pixel electrode 41 may be used as a cathode electrode, and the opposite electrode 45 may be used as an anode electrode.

In some embodiments, when the organic light-emitting display device is a bottom emission type displaying an image toward the substrate 1, the pixel electrode 41 is a transparent electrode and the opposite electrode 45 is a reflective electrode. In some embodiments, reflective electrode may be formed by thinly depositing a metal having a low work function, such as Ag, Mg, Al, Pt, Pd, Au, Ni, Nd, Ir, Cr, Li, Ca, LiF, or a combination thereof

In some aspects of the embodiments illustrated in FIGS. 1 through 12, a back plane can be manufactured using about 7 masks. However, such a process of manufacturing a back plane for use in flat panel displays requires a plurality of mask processes, thus increasing manufacturing costs.

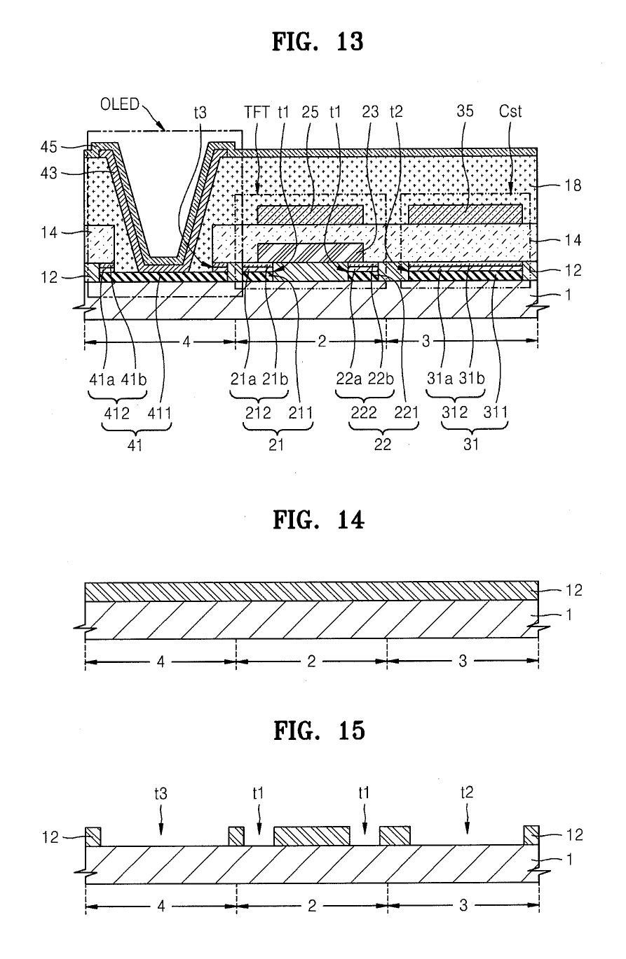

FIG. 13 is a schematic cross-sectional view of a back plane for use in flat panel displays according to another aspect of the present embodiments.

Referring to FIG. 13, the back plane for use in flat panel displays includes a transistor region 2, a storage region 3, and a light-emitting region 4.

In some embodiments, the transistor region 2 includes the TFT serving as a driving device. In some embodiments, the TFT includes an active layer 23, a gate electrode 25, and source and drain electrodes 22 and 21. As illustrated in FIG. 1, the TFT may be a top gate and bottom contact type in terms of structure, and may be an oxide semiconductor TFT in terms of material.

In some embodiments, the source electrode 22 and the drain electrode 21 of the TFT are embedded in a first trench t1 formed in an auxiliary layer 12 on the substrate 1. In some embodiments, the source electrode 22 and the drain electrode 21 include first electrode layers 211 and 221, respectively, and second electrode layers 212 and 222, respectively, sequentially stacked on the substrate 1. In some embodiments, the first electrode layers 211 and 221 may be formed of a transparent conductive material, and the second electrode layers 212 and 222 may be formed of a low-resistance conductive material. In some embodiments, the second electrode layers 212 and 222 can include at least first layers 21a and 22a, respectively, and second layers 21b and 22b, respectively, sequentially stacked on the first electrode layers 211 and 221. In some embodiments, the second layers 21b and 22b can include a low-resistance material that is less reactive to an oxide semiconductor than the first layers 21a and 22a. For example, the first layers 21a and 22a may include aluminum (Al) that is highly reactive to the oxide semiconductor. In some embodiments, the second layer 21b and 22b may include at least one selected from among silver (Ag), magnesium (Mg), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), MoW, and copper (Cu) that is less reactive to oxide semiconductor. In some embodiments, the active layer 23 is formed on the source electrode 22 and the drain electrode 21 so as to contact the source electrode 22 and the drain electrode 21. In some embodiments, a first insulation layer 14 as a gate insulation layer for insulating the gate electrode 25 from the active layer 23 is formed on the auxiliary layer 12 so as to cover the active layer 23. In some embodiments, the gate electrode 25 is formed on the first insulation layer 14 so as to face the active layer 23.

In some embodiments, the storage region 3 can include the capacitor Cst. In some embodiments, the capacitor Cst can include a lower electrode 31 and an upper electrode 35, and the first insulation layer 14 is interposed between the lower electrode 31 and the upper electrode 35. In some embodiments, the lower electrode 31 is embedded in a second trench t2 formed in the auxiliary layer 12 on the substrate 1. In some embodiments, the lower electrode 31 may include a first electrode layer 311 formed of a transparent conductive material and a second electrode layer 312 formed of a low-resistance conductive material, similar to the source electrode 22 and the drain electrode 21, and the second electrode layer 312 may include at least a first layer 31a and a second layer 31b. In some embodiments, the first and second layers 31a and 31b may be formed of the same materials as those used to form the first layers 21a and 22a and the second layers 21b and 22b of the source electrode 22 and the drain electrode 21. In some embodiments, the upper electrode 35 may be formed of the same material as that used to form the gate electrode 25 of the TFT, on the same layer as the layer on which the gate electrode 25 is formed.

In some embodiments, the light-emitting region 4 can include an OLED. In some embodiments, the OLED can include a pixel electrode 41 connected to the source or drain electrode 22 or 21 of the TFT, an opposite electrode 45 formed to face the pixel electrode 41, and an intermediate layer 43 interposed between the pixel electrode 41 and the opposite electrode 45. In some embodiments, the pixel electrode 41 may be formed of a transparent conductive material or may be formed of the same material as that used to form the first electrode layers 211 and 221 of the source and drain electrodes 22 and 21, on the same layer as that on which the first electrode layers 211 and 221 are formed.

FIG. 13 illustrates that the source and drain electrodes 22 and 21 and the lower electrode 31 can include the first electrode layers 211, 221, and 311. In some embodiments, the first electrode layers 211, 221, and 311 can include a transparent conductive material which can be also used to form the pixel electrode 41. According to this co-planar structure, the back plane of FIG. 13 may be manufactured using a smaller number of mask processes than performed to manufacture the back plane of FIG. 1.

FIGS. 14 through 22 are schematic cross-sectional views for describing a method of manufacturing the back plane of FIG. 13.

First, as shown in FIG. 14, the auxiliary layer 12 is formed on an upper surface of the substrate 1.

The auxiliary layer 12, for example, a barrier layer, a blocking layer, and/or a buffer layer, may be formed on the upper surface of the substrate 1 to prevent diffusion of impurity ions and penetration of moisture or external air and to planarize the upper surface of the substrate 1.

First, as shown in FIG. 15, the first trench t1, the second trench t2, and a third trench t3 are formed in the auxiliary layer 12.

In some embodiments, the first trench t1, the second trench t2, and the third trench t3 of the auxiliary layer 12 are formed by patterning according to a mask process that uses a first mask (not shown).

In some embodiments, the first trench t1 is formed in the transistor region 2, the second trench t2 is formed in the storage region 3, and the third trench t3 is formed in the light-emitting region 4. The first, second, and third trenches t1, t2, and t3 may have depths equal to or smaller than the thickness of the auxiliary layer 12.

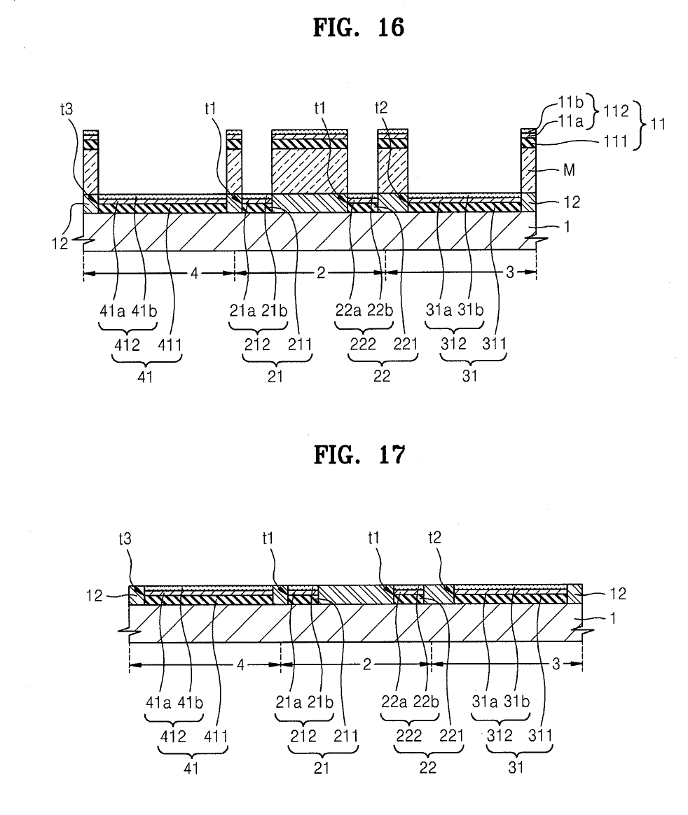

Next, as shown in FIGS. 16 and 17, the source electrode 22 and the drain electrode 21 of the TFT are formed to be embedded in the first trench t1, and the lower electrode 31 of the capacitor Cst is formed to be embedded in the second trench t2. The pixel electrode 41 is formed to be embedded in the third trench t3.

In some embodiments, the source and drain electrodes 22 and 21, the lower electrode 31 of the capacitor Cst, and the pixel electrode 41 are formed by patterning according to a mask process using a second mask (not shown) and a lift-off method.

Referring to FIG. 16, a masking layer M is formed on a portion of the auxiliary layer 12 other than a portion where the first trench t1, the second trench t2, and the third trench t3 have been formed, by using the second mask. Then, a first metal layer 11 is formed on the entire surface of the substrate 1. In some embodiments, the first metal layer 11 is embedded in the first trench t1, the second trench t2, and the third trench t3 and covers the masking layer M. In some embodiments, the first metal layer 11 may include at least a first film 111 and a second film 112 sequentially stacked on the substrate 1. In some embodiments, the first film 111 may include a transparent metal oxide and at least one selected from among transparent materials such as ITO, IZO, ZnO, and In₂O₃. The second film 112 may include at least a first layer 11a and a second layer 11b sequentially stacked on the first film 111. The first layer 11a may include Al, and the second layer 11b may include at least one component selected from the group consisting of silver (Ag), magnesium (Mg), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), MoW, and copper (Cu). In some embodiments, the first conductive layer 11 may have a three-layered structure, namely, an Mo—Al—Mo structure. In some embodiments, the thickness of the first metal layer 11 may be smaller than or equal to the depth of the first, second, or third trenches t1, t2, or t3.

In some embodiments, the masking layer M and a portion of the first metal layer 11 existing on the upper surface of the masking layer M can both be removed to obtain the source and drain electrodes 22 and 21 embedded in the first trench t1 and the lower electrode 31 embedded in the second trench t2 as shown in FIG. 17. In some embodiments, the pixel electrode 41 embedded in the third trench t3 is also obtained. In some embodiments, the source and drain electrodes 22 and 21 include the first electrode layers 211 and 221, respectively, corresponding to the first film 111, and the second electrode layers 212 and 222, respectively, corresponding to the second film 112. In some embodiments, the second electrode layers 212 and 222 include at least the first layers 21a and 22a, respectively, and the second layers 21b and 22b, respectively. In some embodiments, the second electrode layers 212 and 222 may have three-layered structures such as a Mo—Al—Mo structure. In some embodiments, the upper surfaces of the source and drain electrodes 22 and 21 and the lower electrode 31 are on the same level as or lower than the upper surface of the auxiliary layer 12. In some embodiments, the pixel electrode 41 includes a first conductive layer 411 corresponding to the first film 111 and including a transparent metal oxide, and a second conductive layer 412 corresponding to the second film 112 and including a low-resistance conductive material. The second conductive layer 412 includes at least a first layer 41a and a second layer 41b.

According to an aspect of the present embodiments, the upper surfaces of the source and drain electrodes 22 and 21 can be on the same level as or lower than the upper surface of the auxiliary layer 12, so that the first layers 21a and 22a do not protrude out of the auxiliary layer 12. Thus, oxidation of the first layers 21a and 22a due to direct contact with the active layer 23 of FIG. 13 may be prevented. In addition, since the upper surface of the lower electrode 31 is on the same level as or lower than the upper surface of the auxiliary layer 12, the thickness of the first insulation layer 14 of FIG. 13, which acts as a dielectric layer between the lower electrode 31 and the upper electrode 35, may be reduced, thereby increasing the capacity of the capacitor Cst.

Although not shown in the drawings, either the source or drain electrode 22 or 21 (the drain electrode 21 in the present embodiment) can contact the pixel electrode 41.

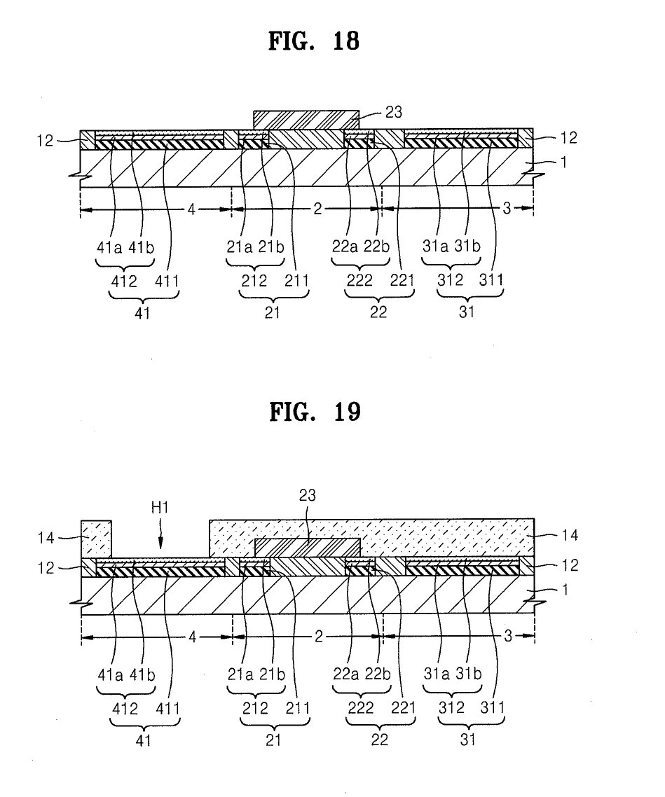

Next, referring to FIG. 18, the active layer 23 is formed on the auxiliary layer 12 so as to contact the source and drain electrodes 22 and 21.

In some embodiments, the active layer 23 is formed by patterning according to a mask process using a third mask (not shown).

In some embodiments, a source area (not shown) and a drain area (not shown) on both edges, respectively, of the active layer 23, are overlapped with at least parts of the upper surfaces of the source and drain electrodes 22 and 21, respectively, and thus are electrically connected to the source and drain electrodes 22 and 21. In some embodiments, the active layer 23 may include an oxide semiconductor. In some embodiments, the oxide semiconductor may include at least one selected from the group consisting of indium (In), gallium (Ga), stannum (Sn), zirconium (Zr), vanadium (V), hafnium (Hf), cadmium (Cd), germanium (Ge), and zinc (Zn). For example, the oxide semiconductor may be formed of Ga, In, and Zn in an atomic percent (atom %) ratio of 2:2:1. However, the formation of the oxide semiconductor is not limited thereto, and the oxide semiconductor may be formed of at least one selected from the group consisting of InGaZnO, Sn0₂, In₂O₃, ZnO, CdO, Cd₂SnO₄, TiO₂, and Ti₃N₄.

Next, as illustrated in FIG. 19, a first insulation layer 14 can be formed on the entire surface of the substrate 1 on which the active layer 23 has been formed, and can be patterned to form a first hole H1 exposing at least a part of the pixel electrode 41.

In some embodiments, the first insulation layer 14 may be obtained by depositing a material such as SiNₓ or SiOₓ according to a method such as PECVD, APCVD, or LPCVD. In some embodiments, the third insulation layer 14 may be formed of at least one organic insulation material selected from the group consisting of polyimide, polyamide (PA), acryl resin, benzocyclobutene (BCB) and phenolic resin by using a method such as spin coating. In some embodiments, the first insulation layer 14 may be formed by alternating an organic insulation material with an inorganic insulation material. In some embodiments, the first insulation layer 14 is disposed between the active layer 23 and the gate electrode 25 of FIG. 13 to serve as a gate insulation layer of the TFT, and also disposed between the upper electrode 35 and the lower electrode 31 of the capacitor Cst to serve as a dielectric layer of the capacitor Cst.

In some embodiments, the first insulation layer 14 may be patterned according to a mask process using a (4_{—}1)th mask (not shown) to form the first hole H1.

In some embodiments, the first hole H1 is formed in the light-emission region 4 and exposes at least a part of the upper surface of the second conductive layer 412 of the pixel electrode 41. In some embodiments, the first hole H1 may expose a part of the upper surface of the second conductive layer 412 as illustrated in FIG. 19, or may expose the entire surface of the pixel electrode 41. However, the present embodiments are not limited thereto.

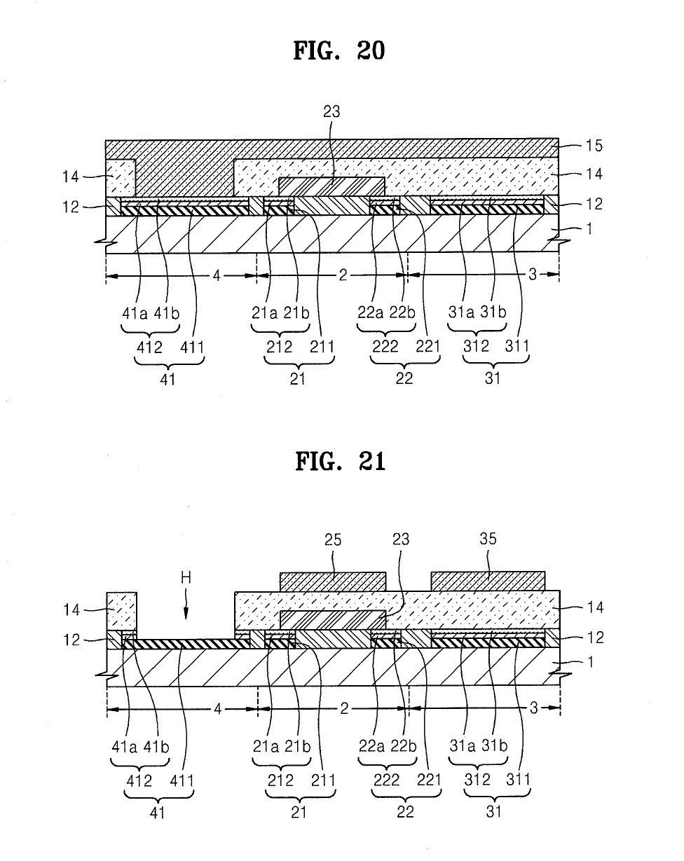

Next, as illustrated in FIG. 20, a second metal layer 15 can be formed on the entire surface of the substrate 1 so as to cover the first insulation layer 14.

In some embodiments, the second metal layer 15 may be formed of one selected from the aforementioned conductive materials used to form the first conductive layer 11, but the material used to form the second metal layer 15 is not limited thereto and may be any of various other conductive materials. In some embodiments, the selected conductive material can be deposited to a sufficient thickness enough to fill the first hole H1.

Next, referring to FIG. 21, the gate electrode 25 and the upper electrode 35 of the capacitor Cst can be formed by patterning the second insulation layer 15.

In some embodiments, the gate electrode 25 and the upper electrode 35 of the capacitor Cst may be formed by patterning according to a mask process using a fourth mask (not shown).

In some embodiments, a hole H can be formed in the pixel electrode 41 at the same time when the gate electrode 25 and the upper electrode 35 are formed. In some embodiments, at least a part of the second conductive layer 412 of the pixel electrode 41 is removed to form the hole H exposing the first conductive layer 411 of the pixel electrode 41. In some embodiments, at least a center portion of the first conductive layer 411 of the pixel electrode 41, which includes a transparent metal oxide, may be exposed.

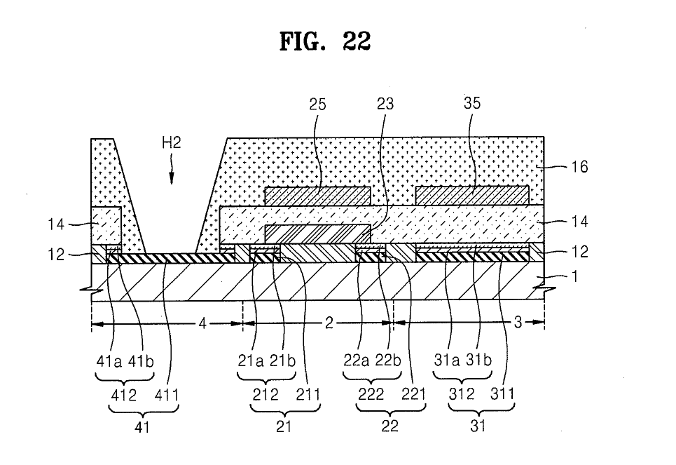

Next, as illustrated in FIG. 22, a second insulation layer 16 can be formed to cover all of the gate electrode 25, the upper electrode 35, and the pixel electrode 41 and is patterned to form a second hole H2 exposing the pixel electrode 41. In this way, a pixel definition layer can be formed.

In some embodiments, the second insulation layer 16 is formed to a sufficient thickness on the entire surface of the substrate 1 on which the pixel electrode 41, the gate electrode 25, and the upper electrode 35 have been formed. In some embodiments, the second insulation layer 16 may be formed of at least one organic insulation material selected from the group consisting of polyimide, polyamide (PA), acryl resin, benzocyclobutene (BCB) and phenolic resin by using a method such as spin coating. In some embodiments, the second insulation layer 16 may be formed of an inorganic insulation material selected from the group consisting of SiO₂, SiNₓ, Al₂O₃, CuOₓ, Tb₄O₇, Y₂O₃, Nb₂O₅, and Pr₂O₃ instead of the above-described organic insulation material. In some embodiments, the second insulation layer 16 may have a multi-layered structure by alternating an organic insulation material with an inorganic insulation material.

In some embodiments, the second insulation layer 16 is patterned according to a mask process using a fifth mask (not shown) to thereby form the second hole H2 exposing a center portion of the pixel electrode 41. In some embodiments, a pixel is defined by this process. Herein, the second hole H2 can contact the first hole H1 or is formed in the first hole H1 to expose at least a part of the pixel electrode 41.

Finally, the intermediate layer 43 of FIG. 13 including an emission layer, and the opposite electrode 45 of FIG. 13 can be formed in the second hole H2 exposing the pixel electrode 41.

In some embodiments, the removal of a stacked layer during each mask process performed to form an organic light emitting display device may be achieved by dry etching or wet etching.

Although a single TFT and a single capacitor are illustrated in the above-described embodiment, this illustration is only for convenience of explanation, that is, the present embodiments is not limited thereto. As long as the number of mask processes used is not increased, a plurality of TFTs and a plurality of capacitors may be included.

According to an aspect of the present embodiments, the thickness of a gate insulation layer is reduced and thus the thickness of a dielectric layer between an upper electrode and a lower electrode of a capacitor is reduced. Accordingly, the capacity of the capacitor can be increased without increasing an aperture ratio.

Moreover, an Al-based layer included in a source electrode and a drain electrode does not directly contact an active layer and thus is not oxidized, so that contact between the active layer and the source and drain electrodes is improved.

Although exemplary embodiments have been described for illustrative purposes, those skilled in the art will appreciate that various modifications, additions and substitutions are possible without departing from the spirit and scope of the present embodiments as defined by the following claims.

What is claimed is:

1. A back plane for use in flat panel displays, the back plane comprising:
a substrate;
an auxiliary layer formed on the substrate and comprising a first trench and a second trench;
a source electrode and a drain electrode formed on the substrate and embedded in the first trench, and a lower capacitor electrode embedded in the second trench and formed on the substrate on which the source electrode and the drain electrode are formed;
an active layer formed on the auxiliary layer to contact the source electrode and the drain electrode;
a first insulation layer formed on the auxiliary layer to cover the active layer;
a gate electrode formed on the first insulation layer to face the active layer, and an upper capacitor electrode formed on the first insulation layer on which the gate electrode is formed, to face the lower capacitor electrode; and
a second insulation layer formed on the first insulation layer to cover the gate electrode and the upper capacitor electrode.

2. The back plane of claim 1, wherein the active layer comprises an oxide semiconductor.

3. The back plane of claim 2, wherein the source electrode and the drain electrode comprise at least a first layer and a second layer sequentially stacked on the substrate, and the second layer comprises a low-resistance material that is less reactive to the oxide semiconductor than the first layer.

4. The back plane of claim 3, wherein the first layer comprises aluminum.

5. The back plane of claim 1, wherein the active layer is overlapped with and contacts at least parts of upper surfaces of the source electrode and the drain electrode.

6. The back plane of claim 1, wherein the source electrode, the drain electrode, and the lower capacitor electrode have upper surfaces that are on the same level as or lower than an upper surface of the auxiliary layer.

7. The back plane of claim 1, further comprising:
a pixel electrode formed on the second insulation layer and electrically connected to the source electrode or the drain electrode;
an intermediate layer formed on the pixel electrode and comprising an organic emission layer; and
an opposite electrode formed on the intermediate layer to face the pixel electrode.

8. The back plane of claim 7, further comprising a third insulation layer formed on the second insulation layer to cover an edge of the pixel electrode, and comprising a hole exposing at least a part of the pixel electrode.

9. The back plane of claim 1, wherein
the auxiliary layer further comprises a third trench, and
the back plane further comprises:
a pixel electrode embedded in the third trench on the substrate, formed on the substrate on which the source electrode and the drain electrode are formed, and electrically connected to the source electrode or the drain electrode;
an intermediate layer formed on the pixel electrode and comprising an organic emission layer; and
an opposite electrode formed on the intermediate layer to face the pixel electrode.

10. The back plane of claim 9, wherein
the first insulation layer comprises a first hole exposing at least a part of the pixel electrode, and
the second insulation layer comprises a second hole that contacts the first hole or is formed in the first hole to expose at least a part of the pixel electrode.

11. The back plane of claim 9, wherein
the source electrode and the drain electrode comprise a first electrode layer including a metal oxide and a second electrode layer including a low-resistance material, and the first and second electrode layers are sequentially stacked on the substrate, and
the pixel electrode comprises a first conductive layer including the metal oxide and a second conductive layer including the low-resistance material, the first and second conductive layers are sequentially stacked on the substrate, and the second conductive layer comprises a hole exposing the first conductive layer.

12. The back plane of claim 11, wherein the second electrode layer comprises at least a first layer and a second layer sequentially stacked on the substrate, and the second layer comprises a low-resistance material that is less reactive to the active layer than the first layer.

13. The back plane of claim 11, wherein the first layer comprises aluminum.

14. A method of manufacturing a back plane for use in flat panel displays, the method comprising:
a first mask process of forming an auxiliary layer on a substrate and forming a first trench and a second trench in the auxiliary layer;
a second mask process of forming a source electrode and a drain electrode on the substrate to be embedded in the first trench, and forming a lower capacitor electrode on the substrate on which the source electrode and the drain electrode are formed, to be embedded in the second trench;
a third mask process of forming an active layer on the auxiliary layer to contact the source electrode and the drain electrode;
forming a first insulation layer on the auxiliary layer to cover the active layer;
a fourth mask process of forming a gate electrode on the first insulation layer to face the active layer, and forming an upper capacitor electrode on the first insulation layer on which the gate electrode is formed, to face the lower capacitor electrode; and
forming a second insulation layer on the first insulation layer to cover the gate electrode and the upper capacitor electrode.

15. The method of claim 14, wherein the active layer comprises an oxide semiconductor.

16. The method of claim 15, wherein the source electrode and the drain electrode comprise at least a first layer and a second layer sequentially stacked on the substrate, and the second layer comprises a low-resistance material that is less reactive to the oxide semiconductor than the first layer.

17. The method of claim 16, wherein the first layer comprises aluminum.

18. The method of claim 14, wherein the active layer is overlapped with and contacts at least parts of upper surfaces of the source electrode and the drain electrode.

19. The method of claim 14, wherein the source electrode, the drain electrode, and the lower capacitor electrode have upper surfaces that are on the same level as or lower than an upper surface of the auxiliary layer.

20. The method of claim 14, wherein the second mask process comprises:
forming a masking layer on a portion of the auxiliary layer other than a portion where the first and second trenches are formed;
forming a metal layer on the entire surface of the substrate to be embedded in the first and second trenches and to cover an upper surface of the masking layer; and
forming a source electrode and a drain electrode embedded in the first trench, and forming a lower capacitor electrode embedded in the second trench, by removing the masking layer.

21. The method of claim 14, further comprising:
a fifth mask process of forming a via hole exposing the source electrode or the drain electrode by penetrating the first insulation layer and the second insulation layer;
a sixth mask process of forming a pixel electrode on the second insulation layer to be electrically connected to the source electrode or the drain electrode that is exposed via the via hole;
forming an intermediate layer on the pixel electrode, the intermediate layer comprising an organic emission layer; and
forming an opposite electrode on the intermediate layer to face the pixel electrode.

22. The method of claim 21, further comprising a seventh mask process of forming a third insulation layer on the second insulation layer to cover an edge of the pixel electrode, the third insulation layer comprising a hole exposing at least a part of the pixel electrode.

23. The method of claim 14, wherein
the first mask process further comprises forming a third trench in the auxiliary layer,
the second mask process further comprises forming a pixel electrode on the substrate on which the source electrode and the drain electrode are formed, to be embedded in the third trench, and to be electrically connected to the source electrode or the drain electrode, and
the method further comprises forming an intermediate layer on the pixel electrode, the intermediate layer comprising an organic emission layer; and forming an opposite electrode on the intermediate layer to face the pixel electrode.

24. The method of claim 23, wherein the second mask process comprises:
forming a masking layer on a portion of the auxiliary layer other than a portion where the first, second, and third trenches are formed;
forming a first metal layer on the entire surface of the substrate to be embedded in the first, second, and third trenches and to cover the upper surface of the masking layer, wherein the first metal layer comprises a first film including a metal oxide and a second film including a low-resistance material, the first and second films sequentially stacked on the substrate; and
forming a source electrode and a drain electrode embedded in the first trench and each of the source electrode and the drain electrode comprising a first electrode layer including a metal oxide and a second electrode layer including a low-resistance material, forming a lower capacitor electrode embedded in the second trench, and forming a pixel electrode embedded in the third trench and comprising a first conductive layer including the metal oxide and a second conductive layer including the low-resistance material, by removing the masking layer, wherein the first and second electrode layers are sequentially stacked on the substrate and the first and second conductive layers are sequentially stacked on the substrate.

25. The method of claim 24, wherein the second electrode layer comprises at least a first layer and a second layer sequentially stacked on the substrate, and the second layer comprises a low-resistance material that is less reactive to the active layer than the first layer.

26. The method of claim 25, wherein the first layer comprises aluminum.

27. The method of claim 24, before the fourth mask process, further comprising a (4_{—}1)th mask process of forming a first hole exposing the second conductive layer of the pixel electrode, on the first insulation layer.

28. The method of claim 27, wherein the fourth mask process comprises:
forming a second metal layer on the entire surface of the substrate to cover the exposed second conductive layer of the pixel electrode; and
forming the gate electrode and the upper capacitor electrode by patterning the second metal layer, and exposing the first conductive layer of the pixel electrode by removing the exposed second conductive layer of the pixel electrode.

29. The method of claim 28, further comprising a fifth mask process of forming a second hole on the second insulation layer, the second hole exposing the first conductive layer of the pixel electrode and contacting the first hole or being formed in the first hole.
